(19) United States
(12) Patent Application Publication
(10) Pub. No.: US 2006/0055056 A1
(43) Pub. Date: Mar. 16, 2006

(54) Semiconductor equipment having a pair of heat radiation plates

(75) Inventors: Shoji Miura, Nutaka-gun (JP); Yoshihiko Ozeki, Nukata-gun (JP); Yoshimi Nakase, Anjo-city (JP); Nobuyuki Kato, Nisshin-city (JP); Tetsuji Kondou, Nagoya-city (JP); Takanori Teshima, Okazaki-city (JP); Naoki Hirasawa, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 10/991,490

(22) Filed: Nov. 19, 2004

(30) Foreign Application Priority Data
Nov. 21, 2003 (JP) 2003-392374
Mar. 18, 2004 (JP) 2004-78243

(51) Int. Cl. H01L 23/48

(52) U.S. Cl. 257/779

(57) ABSTRACT

Semiconductor equipment includes: a semiconductor device; a pair of upper and lower heat radiation plates; and a heat radiation block. The heat radiation block has a planar shape, which is smaller than a planer shape of the semiconductor device. The semiconductor device includes a heat generation portion facing the heat radiation block. The heat generation portion has a periphery edge, which is determined such that a distance between the periphery edge of the heat generation portion and a periphery edge of the heat radiation block is equal to or shorter than 1.0 mm.

### CROSS REFERENCE TO RELATED APPLICATIONS

This application is based on Japanese Patent Applications No. 2003-392374 filed on Nov. 21, 2003, and No. 2004-78243 filed on Mar. 18, 2004, the disclosures of which are incorporated herein by reference.

### FIELD OF THE INVENTION

The present invention relates to semiconductor equipment having a pair of heat radiation plates.

### BACKGROUND OF THE INVENTION

Semiconductor equipment having a pair of heat radiation plates, which are bonded on top and bottom surfaces of the equipment with solder, is disclosed. The semiconductor equipment is suitably used for a semiconductor device, for example, a transistor such as an IGBT (i.e., an insulated gate bipolar transistor) or a diode, which has high withstand voltage and large current capacity and generates large heat when the device works. The above semiconductor equipment is disclosed, for example, in U.S. Pat. No. 6,703,707. In the semiconductor equipment, the heat generated in the semiconductor device is conducted and radiated from the top and the bottom of the equipment through the radiation plates. Thus, the thermal resistance of a package of the semiconductor device becomes smaller. Therefore, the dimensions of the device, the number of the devices and the like can be reduced. Accordingly, the manufacturing cost of the semiconductor equipment is reduced.

However, the connection of the solder has the following problems. If the solder contacts a metallic member, operation fault may occur. Further, a heat radiation performance is not sufficient because thermal path from the semiconductor device through the top and the bottom of the equipment becomes inhomogeneous.

### SUMMARY OF THE INVENTION

In view of the above-described problem, it is an object of the present invention to provide semiconductor equipment having a pair of heat radiation plates. The equipment has sufficient heat radiation performance.

The semiconductor equipment includes a semiconductor device, a pair of upper and lower heat radiation plates, and a heat radiation block. The lower heat radiation plate, the semiconductor device, the heat radiation block and the upper heat radiation plate are disposed in this order. The heat radiation block has a planar shape, which is smaller than that of the semiconductor device. The semiconductor device has a heat generation portion facing the heat radiation block. The heat generation portion has a periphery. A distance between the periphery of the heat generation portion and a periphery of the heat radiation block is equal to or smaller than 1.0 mm.

In the above construction, the heat generation portion of the semiconductor device is disposed under the heat radiation block. Further, the heat radiation portion is provided in such a manner that the periphery of the heat generation portion is not more than 1.0 mm apart from a periphery of the heat radiation block. Therefore, the thermal path of the heat generated in the heat generation portion passes toward up and down directions of the semiconductor device. Thus, the equipment has sufficient heat radiation performance so that temperature rise of the device can be lowered effectively.

Preferably, the heat generation portion is a region, in which a channel current of a main cell in the semiconductor device flows.

Preferably, the heat generation portion is a channel formation region in the main cell of the semiconductor device.

Further, semiconductor equipment includes: a semiconductor device having a main electrode disposed on a principal surface of the semiconductor device; a metal plate disposed on a principal surface side of the semiconductor device and connecting to the main electrode; a package for protecting the semiconductor device, the main electrode and the metal plate. The outline of the main electrode has a polygonal shape, and the outline of the metal plate also has a polygonal shape. A side of the polygonal shape of the metal plate is equal to or shorter than a corresponding side of the polygonal shape of the main electrode.

In the semiconductor equipment having the above construction, a solder layer disposed between the metal plate and the main electrode cannot protrude from an area of the main electrode. Therefore, a part, which necessitates insulation, and a metal part are insulated sufficiently, so that the operation failure is eliminated.

Further, the metal part can be prevented from contacting a wire, so that the operation failure caused by the contact is eliminated.

Further, the insulation of a guard ring formed at a periphery of the wire or the semiconductor device can be assured. Furthermore, a bonding tool is prevented from contacting the metal part. Therefore, a preferable effect is obtained such that a chip size can be optimized to be required dimensions. Further, the metal part and the solder layer adhered to the metal part are prevented from hanging over so that the reduction of the durability of the semiconductor device is prevented.

Preferably, the polygonal shape of the metal plate has no concavity, and the polygonal shape of the main electrode also has no concavity.

Further, semiconductor equipment includes a semiconductor device having a main electrode disposed on a principal surface of the device; a metal plate connecting to the main electrode; and a package for protecting the semiconductor device, the main electrode and the metal plate. The main electrode has a polygonal shape, and the metal plate also has a polygonal shape. The area of the polygonal shape of the metal plate is equal to or smaller than the area of the polygonal shape of the main electrode.

In the semiconductor equipment having the above construction, the solder layer between the metal plate and the main electrode does not protrude from the area of the main electrode. Accordingly, the insulation between the metal part and the part, which necessitates insulation, can be assured sufficiently so that the operation failure is eliminated. Further, the preferable effect is obtained such that a chip size can be optimized to be required dimensions. Furthermore, the reduction of the durability of the semiconductor device is prevented.

### BRIEF DESCRIPTION OF THE DRAWINGS

The above and other objects, features and advantages of the present invention will become more apparent from the following detailed description made with reference to the accompanying drawings. In the drawings:

FIG. 1 is a plan view showing a semiconductor device in semiconductor equipment according to a first embodiment of the present invention;

FIG. 2 is a cross sectional view showing the semiconductor equipment according to the first embodiment;

FIG. 3 is a partially enlarged cross sectional view showing the semiconductor device taken along line III-III in FIG. 1;

FIG. 4 is a partially enlarged cross sectional view showing a main cell;

FIG. 5 is a graph showing a relationship between a distance d and a maximum temperature of the device;

FIG. 6 is a partially enlarged cross sectional view showing a semiconductor device in semiconductor equipment according to a second embodiment of the present invention;

FIG. 7 is a plan view showing a semiconductor device in semiconductor equipment according to a third embodiment of the present invention;

FIG. 8 is a plan view showing a semiconductor device in semiconductor equipment according to a fourth embodiment of the present invention;

FIG. 9 is a plan view showing a semiconductor device in semiconductor equipment according to a comparison of the first embodiment;

FIG. 10 is a cross sectional view showing semiconductor equipment according to a fifth embodiment of the present invention;

FIG. 11A is a plan view, and FIG. 11B is a cross sectional view showing a semiconductor device in the semiconductor equipment according to the fifth embodiment; and

FIG. 12A is a plan view, and FIG. 12B is a cross sectional view showing a semiconductor device in semiconductor equipment according to a sixth embodiment of the present invention.

### DETAILED DESCRIPTION OF THE PREFERRED EMBODIMENTS

### First Embodiment

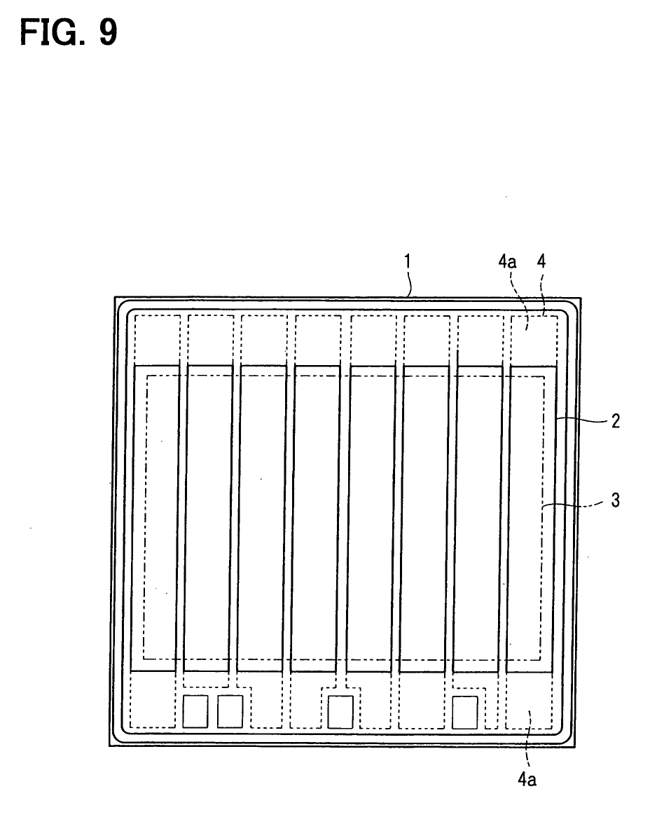

The inventors have preliminarily studied about semiconductor equipment having a top and bottom surface cooling construction. FIG. 9 shows an example of a semiconductor device (i.e., a power device) used in the semiconductor equipment. The semiconductor device 1 shown in FIG. 9 is a well-known general-purpose power device (e.g., an IGBT), which is cooled from one side and is used in a conventional art. A collector electrode is formed on a whole bottom surface of the semiconductor device 1. The collector electrode is bonded to a lower heat radiation plate with solder.

On the other hand, as shown in FIG. 9, multiple emitter electrodes 2 having a rectangular shape is formed on the top surface of the semiconductor device 1. A heat radiation block 3 is bonded to the emitter electrodes 2 with solder. Here, the area of the emitter electrode 2 (i.e., disposed in an opening in a protection film) is smaller than the area of the main cell 4 (i.e., an emitter main cell), in which the emitter current flows.

In this construction, the heat radiation path of heat generated in the main cell 4 disposed under the heat radiation block 3 of the semiconductor device 1 passes toward up and down directions of the device. Therefore, the temperature increase of the device is effectively prevented. However, the heat radiation path of heat generated in a part 4a of the main cell 4 (i.e., a part disposed outside of the heat radiation block 3), which is apart from the heat radiation block 3, passes only downward of the device. Accordingly, the device temperature in the above part 4a becomes higher than the device temperature in another part disposed under the heat radiation block 3. Thus, although the equipment has a construction for radiating heat from both of the top and bottom surfaces of the semiconductor device 1, it is considered that the heat radiation performance is not sufficient.

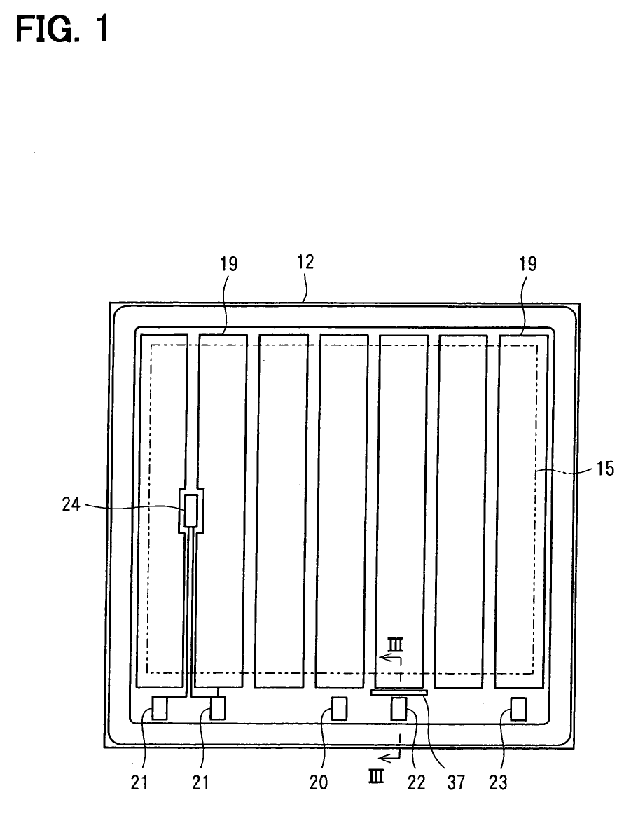

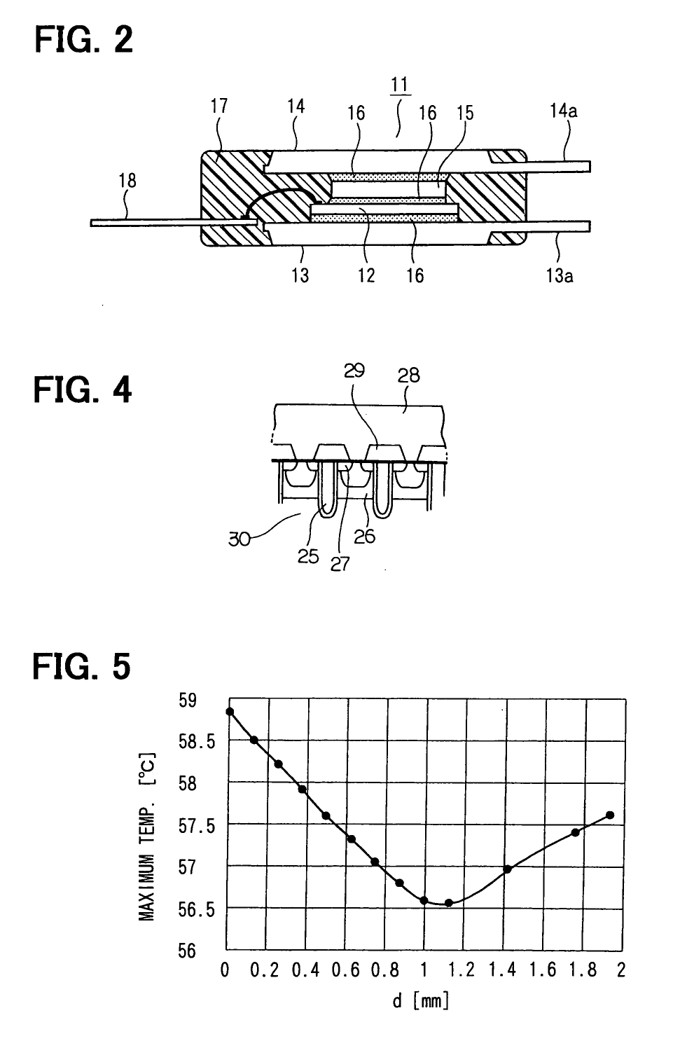

In view of the above problem, semiconductor equipment according to a first embodiment of the present invention is provided. The semiconductor equipment 11 is shown in FIGS. 1 to 4. FIG. 2 is a vertical cross sectional view showing the whole construction of the semiconductor equipment 11. As shown in FIG. 2, the semiconductor equipment 11 includes a semiconductor chip (i.e., a semiconductor device) 12, a lower heat sink (i.e., a heat radiation plate) 13, an upper heat sink (i.e., a heat radiation plate) 14 and a heat sink block (i.e., a heat radiation block) 15.

In this case, the bottom of the semiconductor chip 12 and the top of the lower heat sink 13 are bonded with a solder layer 16 as a bonding member made of solder. Further, the top of the semiconductor chip 12 and the bottom of the heat sink block 15 are also bonded with the solder layer 16. Furthermore, the top of the heat sink block 15 and the bottom of the upper heat sink 14 are bonded with the solder layer 16. Thus, the heat is radiated from both upper and lower surfaces of the semiconductor chip 12 through the heat sinks 13, 14 (i.e., a pair of heat radiation plates).

Here, the above semiconductor chip 12 is a power semiconductor device such as an IGBT, a DMOS, a FWD and a thyristor. The shape of the semiconductor chip 12 in this embodiment is, for example, a rectangular thin plate shape, as shown in FIGS. 1 and 2.

The lower heat sink 13, the upper heat sink 14 and the heat sink block 15 are made of Cu, for example. They can be made of other metals having excellent heat conductivity and electric conductivity such as Al. The lower heat sink 13 and the upper heat sink 14 are electrically connected to main electrodes of the semiconductor chip 12 (e.g., a collector electrode, an emitter electrode and the like).

As shown in FIG. 2, the lower heat sink 13 is almost a rectangular plate shape. A lead (i.e., a lower lead) 13a protrudes from the lower heat sink 13 toward a right direction of FIG. 2, and is integrated with the lower heat sink 13.

The heat sink block 15 has a rectangular plate shape, which is a little smaller than the semiconductor chip 12 (i.e., the heat sink block has a rectangular area shown as a chain double-dashed line in FIG. 1). Further, the upper heat sink 14 is formed of a plate having almost a rectangular shape as a whole. A lead (i.e., an upper lead) 14a protrudes from the upper heat sink 14 toward the right direction of FIG. 2, and is integrated with the upper heat sink 14.

The lead 13a of the lower heat sink 13 and the lead 14a of the upper heat sink 14 are skew each other, i.e., they do not face each other.

The distance between the top of the lower heat sink 13 and the bottom of the upper heat sink 14 is, for example, from 1 mm to 2 mm. A poly amide resin coating (not shown) as a resin coating is applied on the surface of a pair of heat sinks 13, 14 and around the chip 12 and the heat sink block 15.

Further, as shown in FIG. 2, a clearance among a pair of heat sinks 13, 14, a periphery of the chip 12 and the heat sink block 15 are filled and molded with a resin mold (e.g., made of epoxy resin). The above described poly amide resin coating is a coating layer (made of resin) for increasing adhesive force between the resin 17 and the heat sink 13, 14, adhesive force between the resin 17 and the chip 12, and adhesive force between the resin 17 and the heat sink block 15.

A control electrode (e.g., a gate electrode and a signal electrode) of the semiconductor chip 12 is bonded to a lead frame 18.with a bonding wire.

Next, the concrete construction of the semiconductor chip 12 is described with referring to FIGS. 1 to 5. Firstly, the upper construction of the semiconductor chip 12 is described with reference to FIG. 1. Multiple emitter electrodes (e.g., seven emitter electrodes) 19 having a rectangular shape are formed on the top of the semiconductor chip 12. The area of the emitter electrodes 19 provides an area of the main cell. Specifically, the area of the emitter electrodes 19 is almost equal to the area of the main cell.

The gate electrode 20, a pair of electrodes 21 for detecting temperature, an electrode 22 for detecting current, an electrode 23 for emitter are formed on a lower side of the top of the semiconductor chip 12. A temperature sensor 24 is formed on the top of the semiconductor chip 12. Specifically, the sensor 24 is disposed at almost a center between two emitter electrodes 19, which are disposed on a left side of the chip 12.

The heat sink block 15 is bonded to the emitter electrode 19 (i.e., the main cell) on the top of the semiconductor chip 12 with solder in such a manner that the block 15 is disposed on a position shown as a chain double-dashed line in FIG. 1. The formation region of the emitter electrode 19, i.e., the channel formation region of the main cell 19 (i.e., the region of the main cell, in which the channel current flows) is formed in such a manner that the channel formation region is disposed under the heat sink block 15, and the distance between the edge of the heat sink block 15 and the channel formation region is equal to or shorter than 1.0 mm.

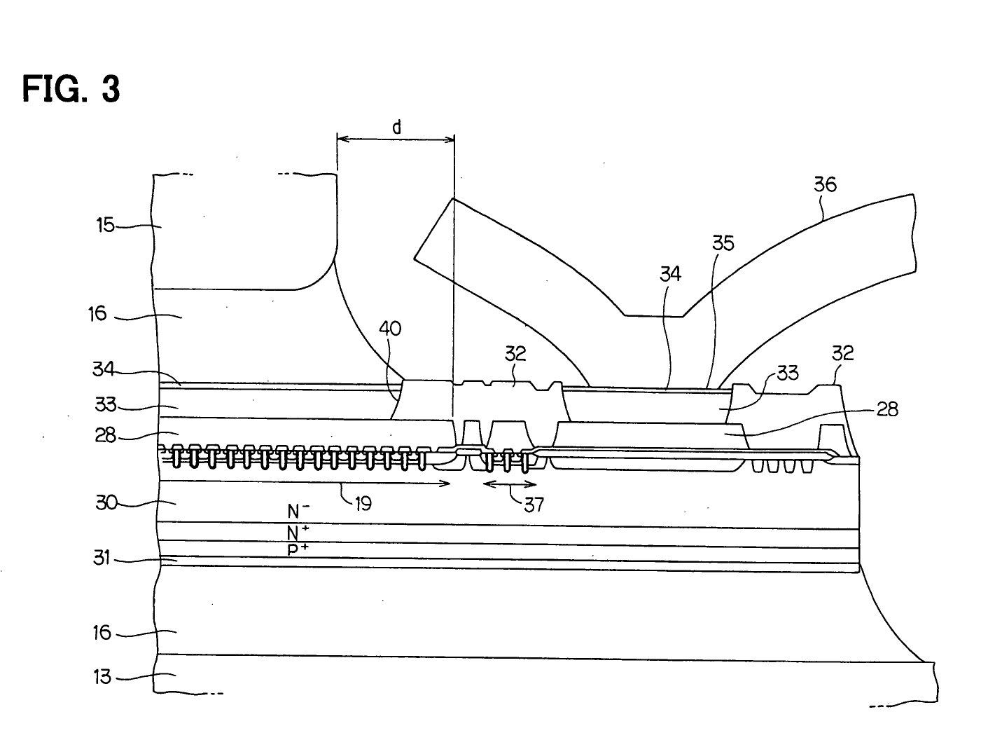

Next, FIG. 3 shows an enlarged cross sectional view taken along line III-III in FIG. 1 in a case where the semiconductor equipment 11 is, for example, a trench type IGBT. Specifically, FIG. 4 is a partially enlarged cross sectional view showing the main cell region 19. As shown in FIG. 4, the main cell region 19 includes a trench gate 25, a P type channel layer 26, an N type emitter layer 27, an emitter aluminum electrode 28 disposed on the surface of the device, an insulation film 29 providing a connection portion (i.e., a contact portion) between the emitter aluminum electrode 28 and a silicon member, a silicon substrate 30 disposed under the emitter aluminum electrode 28, and a backside electrode 31 (See FIG. 3).

In this embodiment, the region, to which the channel electron current flows from the emitter electrode 19, is defined as the main cell region. The main cell region 19 has a construction such that the main cell region 19 is apart from the edge of the heat sink block 15 within 1.0 mm. In this case, a dimension d (i.e., a distance between the edge of the heat sink block 15 and the edge of the main cell region 19) is equal to or smaller than 1.0 mm.

A protection film 32 made of poly imide is formed on the top of the semiconductor chip 12. Further, a nickel plating film 33 and a gold plating film 34 for a solder contact are deposited in an opening of the protection film 32 disposed on the top of the emitter aluminum electrode 28. The gold plating film 34 provides the emitter electrode 19. The heat sink block 15 is bonded to the gold plating film 34 through the solder layer 16.

Further, as shown in FIG. 3, an electrode pad 35 for a signal is formed on a right side of the top of the semiconductor chip 12. The electrode pad 35 provides a gate electrode 20, a pair of electrodes 21 for detecting the temperature of the device 12, an electrode 22 for detecting the current of the device, and an electrode 23 for an emitter.

The above electrode pad 35 includes an aluminum electrode 28, the nickel plating film 33 and the gold plating film 34. The nickel plating film 33 and the gold plating film 34 for the bonding wire are deposited on the top of the aluminum electrode 28 corresponding to the opening of the protection film 32.

In this case, a bonding wire 36 having a diameter of, for example, 150 μm is bonded on the electrode pad 35 (i.e., on the gold plating film 34) for the signal by a wire bonding method. To avoid overlapping between the bonding wire 36 and the heat sink block 15, it is required for a distance between a bonding coordinate center and the heat sink block 15 to be equal to or longer than 0.7 mm. Further, when the diameter of the bonding wire 36 is 150 μm, it is required for a pad size (i.e., an electrode size) in a longitudinal direction to be about 0.6 mm.

Furthermore, each electrode pad 35 (i.e., the gate electrode 20, the electrode 21 for detecting temperature, the electrode 22 for detecting current, or the electrode 23 for the emitter) for the signal is disposed apart from the heat sink block 15 to be equal to or longer than 1.0 mm. Further, multiple electrode pads 35 are aligned in a line and disposed on one side of the top of the semiconductor chip 12 (See FIG. 1). In this case, the main cell region 19 is not disposed around the electrode 35 for the signal.

As shown in FIG. 3, a current detection region 37 is formed on the right side of the main cell region 19 in the semiconductor chip 12. The current detection region 37 is formed to be the same construction as the main cell region 19. However, the area of the current detection region 37 is about a ten thousandth of the area of the main cell region 19. When a main current of, for example, 400 A flows in the main cell, a small current signal of 40 mA, which is about 1/10000 of the main current, can be monitored.

Further, in a practical system circuit, the above small current signal is detected by a sensor resistance so that a small current about 1/20000 of the main current, which is a half of a diversion current ratio of 1/10000, flows in the system circuit. Therefore, a heat value per unit area (i.e., a heat density) in the current detection region 37 is about a half of a heat density in the main cell region. Accordingly, the current detection region 37 has small heat radiation so that it is no need to radiate the heat from both sides of the equipment. Therefore, the current detection region 37 can be disposed apart from the heat sink block 15. Thus, the device area is effectively available.

The temperature sensor 24 disposed on the semiconductor chip 12 includes a P—N junction in a poly silicon layer of the device so that the sensor 24 detects a temperature of the semiconductor chip 12 by using a temperature dependence of a Vf (i.e., a forward voltage) of a diode. The temperature sensor 24 is disposed under the heat sink block 15, of which the device temperature increases. Here, in this embodiment, the temperature sensor 24 is disposed to shift from the center portion of the main cell region 19. It is preferred that the temperature sensor 24 is disposed at the center portion.

Next, the reason why the main cell region 19 is disposed apart from the edge of the heat sink block 15 within 1.0 mm is described as follows with reference to FIG. 5. A graph in FIG. 5 shows a relationship between a dimension d (i.e., a distance between the edge of the heat sink block 15 and the edge of the main cell region 19) and a temperature of a part of the semiconductor chip 12, of which the temperature becomes highest. The graph is obtained by a simulation result.

In FIG. 5, each point (i.e., each measurement point), of which the dimension d is equal to or shorter than 1 mm, represents the temperature of the center portion of the semiconductor chip 12 disposed under the heat sink block 15. Each point, of which the dimension d is equal to or longer than 1 mm, represents the temperature of the semiconductor chip 12 disposed outside the heat sink block 15 (i.e., the edge portion of the semiconductor chip 12). Specifically, the graph in FIG. 5 shows that the portion of the semiconductor chip 12 that is the maximum temperature increase portion is disposed under the heat sink block 15 in a case where the dimension d is equal to or shorter than 1 mm. Therefore, the generated heat is radiated sufficiently from both of the top and the bottom of the device. On the other hand, the portion of the semiconductor chip 12 that is the maximum temperature increase portion is disposed outside of the heat sink block 15 in a case where the dimension d is equal to or longer than 1 mm. Therefore, the generated heat is radiated only from the bottom of the device so that the heat radiation performance is not sufficient.

In the above construction of this embodiment, the main cell region 19 disposed on the top of the semiconductor chip 12 (i.e., the channel formation region of the main cell or the region of the main cell in which the channel current flows) is disposed under the heat sink block 15. Further, the main cell region 19 is disposed to be equal to or shorter than 1.0 mm apart from the edge of the heat sink block 15. Therefore, the heat radiation path of the heat generated in the main cell region 19 passes in the up and down direction of the semiconductor chip 12 so that the sufficient heat radiation performance is obtained. Thus, the device temperature increase is effectively reduced.

Here, it is preferred that the channel formation region of the main cell or the region of the main cell, in which the channel current flows, disposed on the top of the semiconductor chip 12 is disposed under the heat sink block 15, and that the main cell region 19 is disposed apart from the edge of the opening 40 in the protection film in the main cell region within 1.0 mm, wherein the opening 40 for the solder bonding connects to the heat sink block 15.

Further, although the upper heat sink block 14 and the heat sink block 15 are independent each other, they can be integrally formed.

### Second Embodiment

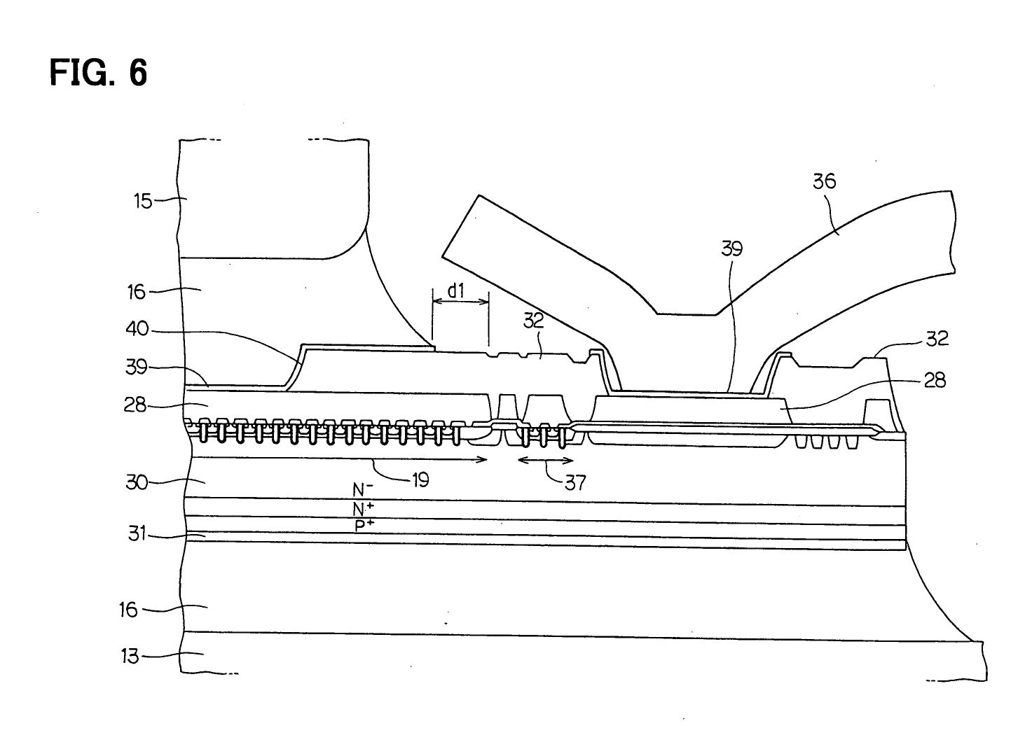

FIG. 6 shows a part of semiconductor equipment according to a second embodiment of the present invention. In the semiconductor equipment, the main cell region 19 is disposed under the heat sink block 15. Further, the main cell region is constructed to be equal to or shorter than 1.0 mm apart from the edge of the solder layer 16 for connecting to the heat sink block 15. Specifically, a dimension d1 shown in FIG. 6 (i.e., a distance between the edge of the solder layer 16 and the edge of the main cell region 19) is equal to or shorter than 1.0 mm. Here, in FIG. 6, a layer shown as reference numeral 39 is an electrode for a surface solder layer made of, for example, TiNiAu.

Thus, the main cell region 19 disposed on the top of the semiconductor chip 12, that is the channel formation region of the main cell or the region of the main cell, in which the channel current flows, is disposed under the heat sink block 15. Further, the main cell region 19 is constructed to be apart from the edge of the solder layer 16 for connecting to the heat sink block 15 within 1.0 mm.

In this case, the channel formation region of the main cell or the region of the main cell, in which the channel current flows, is disposed under the heat sink block 15. Further, the main cell region 19 is constructed to be apart from the edge of the electrode 39 (See FIG. 6) for the solder bonding for connecting to the heat sink block 15 within 1.0 mm.

In the above construction according to this embodiment, the heat radiation path of the heat generated in the main cell region 19 passes toward the up and the down directions of the semiconductor chip 12. Therefore, the sufficient heat radiation performance is obtained so that the device temperature increase is effectively prevented.

Further, it is preferred that the channel formation region of the main cell disposed on the top of the semiconductor chip 12 or the region of the main cell, in which the channel current flows, is disposed under the heat sink block 15, and the main cell region 19 is constructed to be apart from the edge of the opening 40in the protection film of the main cell region for the solder bonding for connecting to the heat sink block 15 within 1.0 mm.

### Third Embodiment

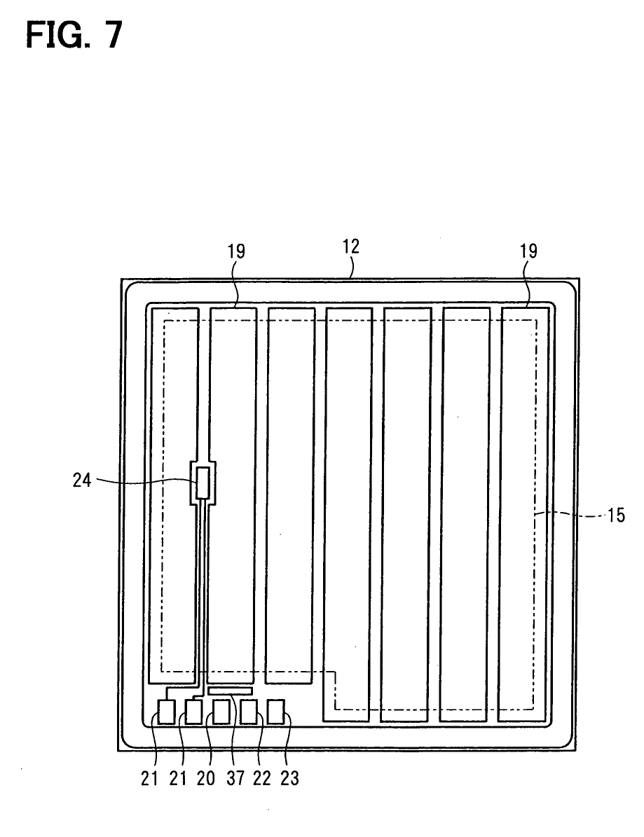

FIG. 7 shows a semiconductor device of semiconductor equipment according to a third embodiment of the present invention. In this semiconductor device, a pad for connecting to a signal wire and a current mirror are arranged to concentrate at one portion disposed on the top of the semiconductor chip 12.

Specifically, the electrode 20, 21, 22, 23 for the signal (i.e., the pad for connecting to the signal wire) and the current detection region 37 (i.e., the current mirror) are disposed to concentrate at a left half of the lower side of the top of the semiconductor chip 12.

Thus, the heat radiation path of the heat generated in the main cell region 19 passes toward the up and the down directions of the semiconductor chip 12. Thus, the sufficient heat radiation performance is obtained so that the device temperature increase is effectively prevented.

Further, since the pad for connecting to the signal wire and the current mirror are disposed to concentrate at one portion of the top of the semiconductor chip 12, the main cell region becomes larger; and therefore, the heat radiation performance is much improved.

### Fourth Embodiment

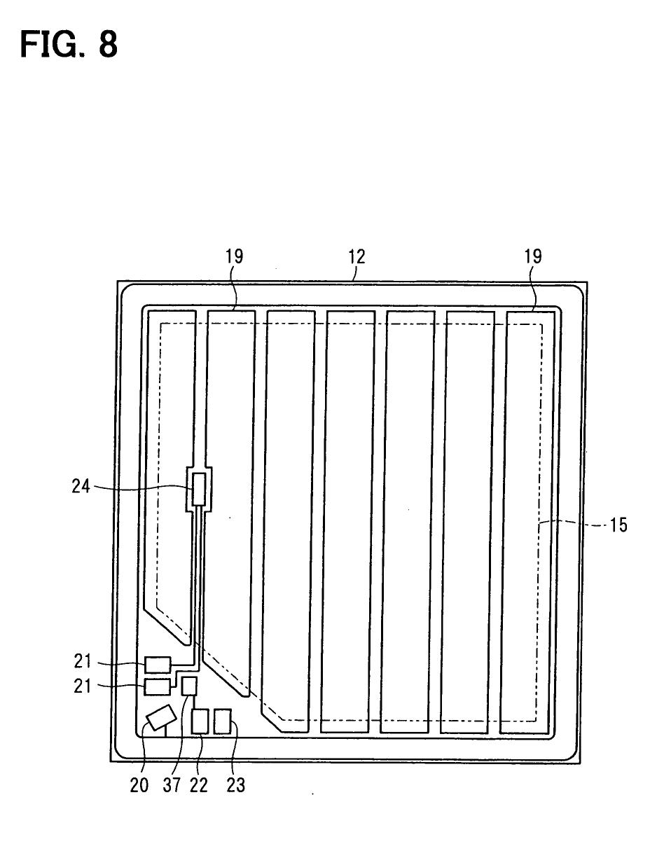

FIG. 8 shows a semiconductor device of semiconductor equipment according to a fourth embodiment of the present invention. In this semiconductor device, when the pad for connecting to the signal wire and the current mirror are disposed to concentrate at one portion of the top of the semiconductor chip 12, the signal electrode 20, 21, 22, 23 (the pad for connecting to the signal wire) and the current detection region 37 (i.e., the current mirror) are disposed to concentrate at one corner (e.g., a left lower corner) of the top of the semiconductor chip 12.

Thus, the heat radiation path of the heat generated in the main cell region 19 passes toward the up and the down directions of the semiconductor chip 12 so that the sufficient heat performance is obtained. Therefore, the device temperature increase is effectively prevented. Further, the main cell region becomes larger, so that the heat radiation performance is much improved.

### Fifth Embodiment

Here, the inventors have preliminarily studied about semiconductor equipment having a top and bottom surface cooling construction. Specifically, in the package type semiconductor equipment having a pair of heat radiation plates, the following problems are generated when a metal member combining a heat sink and an electrode is bonded with solder on an electrode formed on a surface of the semiconductor device.

(1) The melted solder protrudes from the periphery of the device so that the solder shorts the metal member bonded to the backside of the semiconductor device. Thus, the operation failure may occur.

(2) The metal member and an adhesive adhered on the metal member are hanged over so that they contacts the bonding wire. Thus, the operation failure may occur.

(3) The chip size becomes excessively larger, since the insulation of the bonding wire and the guard ring is required.

(4) To assure a sufficient distance to prevent a tool for wire bonding and the metal member from interrupting each other, the chip size becomes larger.

(5) A separation stress generated by a resin mold penetrating between the over hang portion of the metal member and the semiconductor device reduce the durability of the device.

In view of the above problems, the inventors have studied about the reason of the above problems. It is determined that the dimensions of the metal member in relation to the dimensions of the surface electrode relates to the above problems. Specifically, it is determined that the above problems occur when the dimensions of the metal member are much larger than the dimensions of the surface electrode.

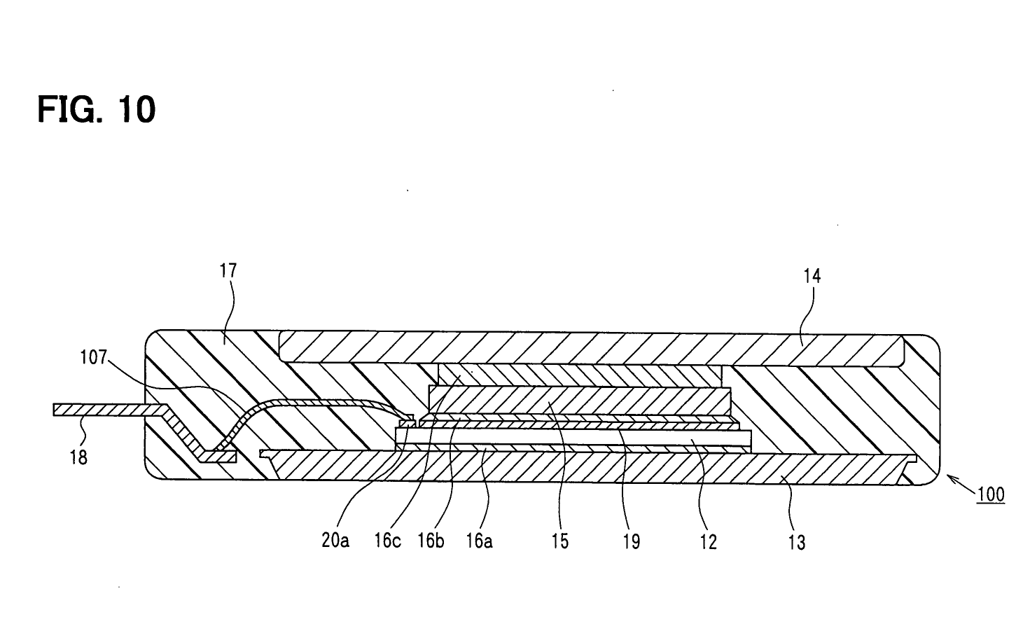

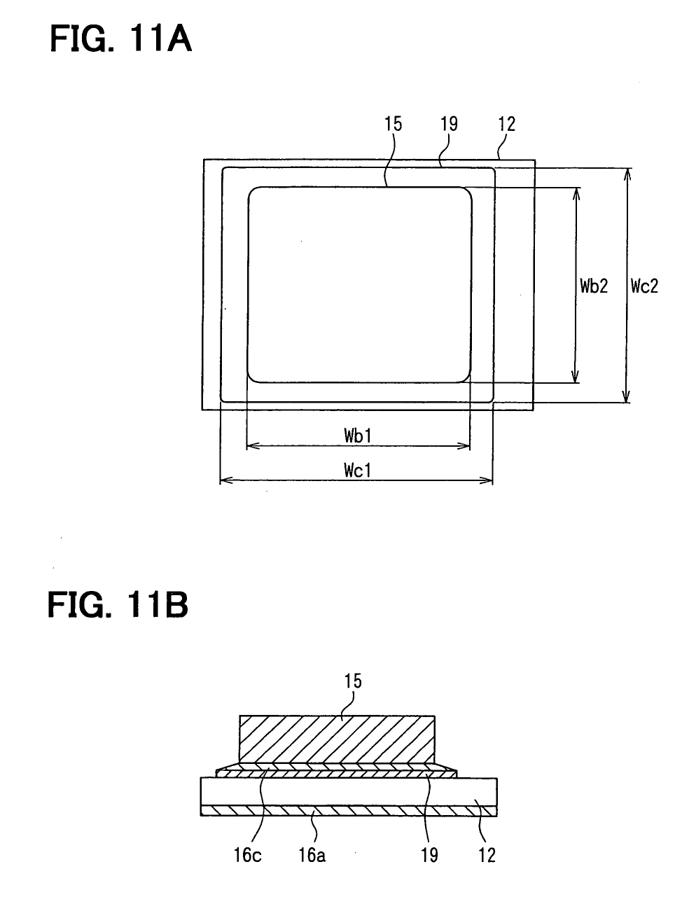

FIG. 10 shows a cross sectional view of package type semiconductor equipment according to a fifth embodiment of the present invention. FIGS. 11A and 11B show a top view and a side view of a part of the package type semiconductor equipment shown in FIG. 10 before packaging. The construction of the package type semiconductor equipment is described as follows with reference to the drawings.

As shown in FIG. 10, the package type semiconductor equipment 100 includes a semiconductor chip 12 having an IGBT as a semiconductor device, the first metal member 13 as a lower heat sink, the second metal member 14 as an upper heat sink, and the third metal member 15 disposed between the second metal member 14 and the semiconductor chip 12, all of which are molded with resin mold 17. A gate electrode pad 20a and a lead terminal 18 are connected with a wire 107. The gate electrode pad 20a electrically connects to a gate electrode (i.e., the second region) of the IGBT in the semiconductor chip 12. One surface of each of the first and the second metal members 13, 14 and one end of the lead terminal 18 are exposed from the resin mold 17 corresponding to the package.

Three solder layers 16a, 16b, 16c as a bonding member bond between the top of the first metal member 13 and the bottom of the semiconductor chip 12, between the top of the semiconductor chip 12 and the bottom of the third metal member 15, and between the top of the third metal member 15 and the bottom of the second metal member 14, respectively. As shown in FIG. 2A, the emitter electrode 19 as the main cell region electrically connects to the emitter region (i.e., the first region) of the IGBT formed on the surface of the semiconductor chip 12. The emitter electrode 19 electrically connects to an external circuit through the second and the third metal members 14, 15. A collector electrode (not shown) for electrically connecting to a collector region of the IGBT is formed on the backside of the semiconductor chip 12. The collector electrode electrically connects to the external circuit through the first metal member 13.

Here, each of the first and the second metal members 13, 14 is connected to a lead terminal not shown so that the first and the second metal members 13, 14 are electrically connected to the external circuit through the lead terminals.

Further, the first and the second metal members 13, 14 work as a pair of heat radiation plates for radiating heat generated in the semiconductor chip 12. Thus, the members 13, 14 are made of copper or the like, which has excellent heat conductivity and low electric resistance. Further, the third metal member 15 works as a thermal path for conducting the heat generated in the semiconductor chip 12 to the second metal member side. The third metal member 15 is made of, for example, copper or the like.

In the package type semiconductor equipment 100 having the above construction, as shown in FIG. 2, the semiconductor chip 12 is formed to be a rectangular shape, and the emitter electrode 19 and the third metal member 15 are formed to be a square shape in a plan view. All surface of the emitter electrode 19 is covered with the solder layer 16b. Looking the semiconductor chip 12 from the top view, the third metal member 15 accommodates in an outline of the emitter electrode 19 so that the third metal member 15 does not protrude from the outline.

Further, the dimension of the side of each of the emitter electrode 19 and the third metal member 15, which is parallel to a longitudinal direction of the semiconductor chip 12, is defined as Wc1, Wb1, respectively. The relationship between the dimension Wc1 of the emitter electrode 19 and the dimension Wb1 of the third metal member 15 is Wc1≧Wb1. Further, the dimension of the side of each of the emitter electrode 19 and the third metal member 15, which is parallel to a latitudinal direction of the semiconductor chip 12, is defined as Wc2, Wb2, respectively. The relationship between the dimension Wc2 of the emitter electrode 19 and the dimension Wb2 of the third metal member 15 is Wc2≧Wb2. Furthermore, in view of the heat radiation performance, the solder layer 16b is designed to be equal to or smaller than the heat generation region.

In the package type semiconductor equipment 100 having the above construction, each length Wb1, Wb2 of the sides of the third metal member 15 in the longitudinal and the latitudinal directions is equal to or shorter than the length Wc1, Wc2 of the corresponding side of the emitter electrode 19 in the longitudinal or the latitudinal direction. Thus, when the third metal member 15 is bonded to the emitter electrode 19 with the solder layer 16, it is performed that the solder layer 16b does not protrude from the area of the emitter electrode 19.

Thus, the third metal member 15 can be sufficiently insulated from a part, which is required to have insulation. For example, it is prevented that the solder layer 16b penetrates round the backside of the semiconductor chip 12 so that the collector electrode disposed on the backside of the semiconductor chip 12 shorts the emitter electrode 19. Therefore, the operation failure according to this short is eliminated.

Further, it is eliminated that the third metal member 15 and the solder layer 16b adhered to the member 15 are hanged over so that they protrude from the emitter electrode 19 just like a canopy. Therefore, the wire 107 is prevented from contacting the third metal member 15. Thus, the operation failure is eliminated.

In a case where the relationship between the dimensions of the third metal member 15 and the dimensions of the emitter electrode 19 is not determined in the prior art, it is required to increase the chip size for ensuring the insulation between the third metal member 15 and the wire 107 or the guard ring formed on the periphery of the semiconductor chip even when the third metal member 15 protrudes from the emitter electrode 19. Further, it is required to set a certain distance between the third metal member 15 and a connection region of the wire 107 for preventing the bonding tool from contacting the third metal member 15 when the wire 107 is bonded. Thus, it is required to increase the chip size.

However, when the dimensions of the third metal member 15 and the emitter electrode 19 are defined appropriately in this embodiment, the insulation between the wire 107 and the guard ring formed on the periphery of the semiconductor device can be secured. Further, the bonding tool is prevented from contacting the third metal member 15. Thus, the advantage for minimizing the chip size is obtained.

Furthermore, even when the third metal member 15 and the solder layer 16b adhered to the member 15 are hanged over, the resin mold penetrates between the semiconductor chip 12 and the solder layer 16b; and therefore, the resin mold generates the separation stress so that the durability of the semiconductor device is reduced by the stress. However, in this embodiment, the third metal member 15 and the solder layer 16b adhered to the member 15 are prevented from hanging over. Therefore, the durability of the semiconductor device is prevented from reducing.

Although the semiconductor device is the IGBT, the semiconductor device can be formed of any device (e.g., a MOSFET). Further, the above advantage is obtained even when the device has no wire 107 shown in FIG. 10 as long as the relationship between the lengths of the sides of the metal member and the electrode or the relationship between the areas of the metal member and the electrode is approved. It is considered that this type of device is, for example, a diode.

Although the metal members 14, 15 are independent each other, they can be integrally formed.

### Sixth Embodiment

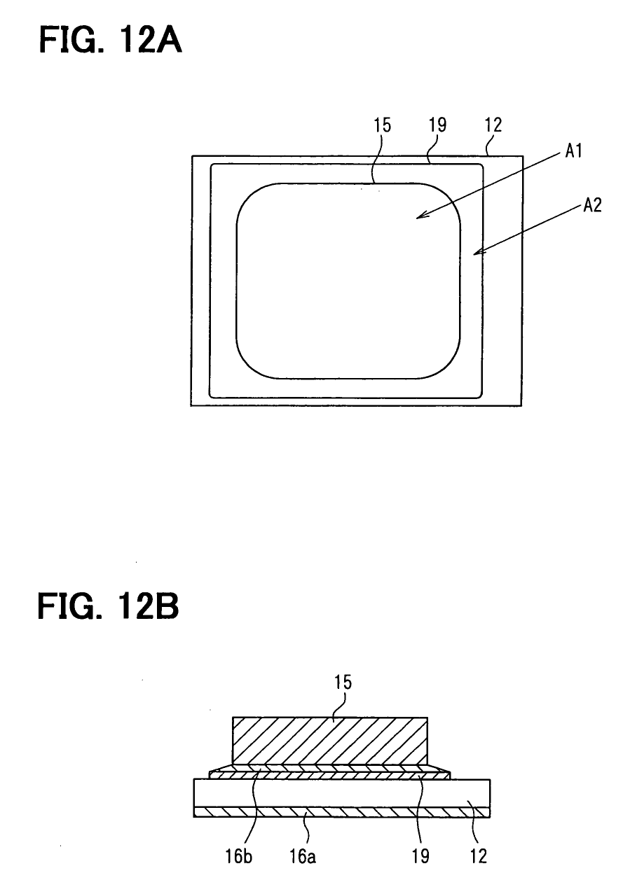

FIGS. 12A and 12B are a top view and a side view showing a part of package type semiconductor equipment according to a sixth embodiment of the present invention before the device is packaged. In this semiconductor equipment, the areas of the emitter electrode 19 and the third metal member 15 are defined instead of the relationship of the dimension of each side of the emitter electrode 19 and the third metal member 15 defined in the semiconductor equipment 100 according to the fifth embodiment. Specifically, when the areas of the third metal member 15 and the emitter electrode 19 are defined as A1 and A2 looking from the top view, the relationship of the areas is set to be A1≦A2. This is, the ratio of areas (A1/A2), i.e., the ratio between a connection area of the emitter electrode 19 and the solder layer 16b and another connection area of the third metal member 15 and the solder layer 16b, is set to be equal to or smaller than 1.

Thus, by defining the ratio between areas of the emitter electrode 19 and the third metal member 15, it is performed that the solder layer 16b does not protrude from the area of the emitter electrode 19. Further, the emitter electrode 19 is prevented from shorting the collector electrode disposed on the backside of the semiconductor chip 12. Thus, the operation failure caused by the short is eliminated. Further, the wire 107 and the third metal member 15 are prevented from contacting each other; and therefore, the operation failure caused by the contact is eliminated. Furthermore, the wire 107 and the guard ring formed on the periphery of the semiconductor device are insulated each other. The bonding tool is prevented from contacting the third metal member 15. Thus, the advantage for minimizing the chip size is obtained. Further, the third metal member 15 and the solder layer 16b adhered to the member 15 are prevented from hanging over; and therefore, the reduction of the durability of the semiconductor device is prevented.

In the above embodiment, the emitter electrode 19 corresponding to the electrode formed on the surface of the semiconductor chip has a square shape, and the third metal member 15 mounted on the emitter electrode 19 has also a square shape. However, they can have another shape (e.g., a polygonal shape). Further, even when they have the other shape except for the square shape, it is performed that a part of the third metal member 15, which is connected to the electrode, has an area, which is equal to or smaller than an area of the surface electrode.

Such changes and modifications are to be understood as being within the scope of the present invention as defined by the appended claims.

What is claimed is:

1. Semiconductor equipment comprising:
a semiconductor device;
a pair of upper and lower heat radiation plates; and
a heat radiation block,
wherein the lower heat radiation plate, the semiconductor device, the heat radiation block and the upper heat radiation plate are disposed in this order,
wherein the heat radiation block has a planar shape, which is smaller than a planer shape of the semiconductor device,
wherein the semiconductor device includes a heat generation portion facing the heat radiation block, and
wherein the heat generation portion has a periphery edge, which is determined in such a manner that a distance between the periphery edge of the heat generation portion and a periphery edge of the heat radiation block is equal to or shorter than 1.0 mm.

2. The semiconductor equipment according to claim 1,
wherein the heat generation portion is a region, in which a channel current of a main cell in the semiconductor device flows.

3. The semiconductor equipment according to claim 1,
wherein the heat generation portion is a channel formation region of a main cell in the semiconductor device.

4. The semiconductor equipment according to claim 1, further comprising:
a solder layer,
wherein the solder layer is disposed between the upper heat radiation plate and the heat radiation block, between the heat radiation block and the semiconductor device, and between the semiconductor device and the lower heat radiation plate, respectively.

5. The semiconductor equipment according to claim 4,
wherein the solder layer disposed between the heat radiation block and the semiconductor device has a periphery edge, which is determined in such a manner that a distance between the periphery edge of the solder layer and a periphery edge of the heat generation portion is equal to or shorter than 1.0 mm.

6. The semiconductor equipment according to claim 4,
wherein the semiconductor device includes an electrode for connecting to the solder layer, and
wherein the electrode has a periphery edge, which is determined in such a manner that a distance between the periphery edge of the electrode and a periphery edge of the heat generation portion is equal to or shorter than 1.0 mm.

7. The semiconductor equipment according to claim 4,
wherein the heat generation portion is a channel formation region of a main cell in the semiconductor device,
wherein semiconductor device includes a protection film for protecting the main cell,
wherein the protection film includes an opening for connecting to the solder layer, and
wherein the opening has a periphery edge, which is determined in such a manner that a distance between the periphery edge of the opening and a periphery edge of the heat generation portion is equal to or shorter than 1.0 mm.

8. The semiconductor equipment according to claim 1, further comprising:
an electrode pad for connecting between the semiconductor device and an external circuit,
wherein the electrode pad is electrically connected to the external circuit with a wire,
wherein the heat generation portion is a channel formation region of a main cell in the semiconductor device, and
wherein the electrode pad is disposed on a surface of the semiconductor device on a heat radiation block side, disposed on a region except for the main cell, and disposed outside of the heat radiation block not to face the heat radiation block.

9. The semiconductor equipment according to claim 8,
wherein the semiconductor device has a square shape, and
wherein the electrode pad is disposed along with a side of the square shape.

10. The semiconductor equipment according to claim 1, further comprising:
a temperature sensor for detecting a temperature of the semiconductor device,
wherein the temperature sensor is disposed on a surface of the semiconductor device on the heat radiation block side, and disposed inside of the heat radiation block to face the heat radiation block.

11. The semiconductor equipment according to claim 10,
wherein the temperature sensor is disposed at a center portion of the semiconductor device.

12. The semiconductor equipment according to claim 1, further comprising:
a solder layer; and
a current detection portion for detecting current of the semiconductor device,
wherein the solder layer is disposed between the upper heat radiation plate and the heat radiation block, between the heat radiation block and the semiconductor device, and between the semiconductor device and the lower heat radiation plate, respectively, and
wherein the current detection portion is disposed on a surface of the semiconductor device on the heat radiation block side, and disposed outside of the solder layer between the heat radiation block and the semiconductor device.

13. The semiconductor equipment according to claim 12,
wherein the current detection portion is a current mirror.

14. The semiconductor equipment according to claim 12, further comprising:
an electrode pad for connecting between the semiconductor device and an external circuit,
wherein the electrode pad is electrically connected to the external circuit with a wire,
wherein the heat generation portion is a channel formation region of a main cell in the semiconductor device, and
wherein the electrode pad is disposed on a surface of the semiconductor device on a heat radiation block side, disposed on a region except for the main cell, and disposed outside of the heat radiation block not to face the heat radiation block, and
wherein the electrode pad and the current detection portion are concentrated in one region of the semiconductor device.

15. Semiconductor equipment comprising:
a semiconductor device having a main electrode disposed on a principal surface of the semiconductor device;
a metal plate disposed on the principal side of the semiconductor device and connecting to the main electrode; and
a package for protecting the semiconductor device, the main electrode and the metal plate,
wherein the main electrode includes an outline having a polygonal shape, and the metal plate includes an outline having a polygonal shape, and
wherein the polygonal shape of the metal plate has a side, which is equal to or shorter than a corresponding side of the polygonal shape of the main electrode.

16. The semiconductor equipment according to claim 15,
wherein the polygonal shape of the metal plate has no concavity, and the polygonal shape of the main electrode has no concavity.

17. The semiconductor equipment according to claim 15, further comprising:
a wire disposed on the principal surface of the semiconductor device,
wherein the wire is capable of controlling a voltage to be applied to the semiconductor device.

18. The semiconductor equipment according to claim 15,
wherein the metal plate is connected to the main electrode through a bonding member, and
wherein the bonding member covers whole of the main electrode.

19. The semiconductor equipment according to claim 15,
wherein the polygonal shape of the metal plate is disposed inside of the polygonal shape of the main electrode.

20. Semiconductor equipment comprising:
a semiconductor device having a main electrode disposed on a principal surface of the semiconductor device;
a metal plate disposed on the principal side of the semiconductor device and connecting to the main electrode; and
a package for protecting the semiconductor device, the main electrode and the metal plate,
wherein the main electrode has a polygonal shape, and the metal plate has a polygonal shape, and
wherein the polygonal shape of the metal plate has an area, which is equal to or smaller than an area of the polygonal shape of the main electrode.

21. The semiconductor equipment according to claim 20, further comprising:
a wire disposed on the principal surface of the semiconductor device,
wherein the wire is capable of controlling a voltage to be applied to the semiconductor device.

22. The semiconductor equipment according to claim 20,
wherein the metal plate is connected to the main electrode through a bonding member, and
wherein the bonding member covers whole of the main electrode.

23. The semiconductor equipment according to claim 20,
wherein the polygonal shape of the metal plate is disposed inside of the polygonal shape of the main electrode.
